(19) United States
(12) Patent Application Publication
(10) Pub. No.: US 2025/0280719 A1
(43) Pub. Date: Sep. 4, 2025

(54) DISPLAY DEVICE

(71) Applicant: LG Display Co., Ltd., Seoul (KR)

(72) Inventor: Hyeonjeong SHIN, Paju-si (KR)

(21) Appl. No.: 18/961,358

(22) Filed: Nov. 26, 2024

(30) Foreign Application Priority Data
Feb. 29, 2024 (KR) 10-2024-0029868

(51) Int. Cl. H10K 59/80; H10K 59/122

(52) U.S. Cl. CPC H10K 59/8792; H10K 59/122

(57) ABSTRACT

Disclosed is a display device comprising a substrate including a first sub-pixel and a second sub-pixel a first electrode disposed on the substrate and disposed on each of the first sub-pixel and the second sub-pixel, a light emitting layer disposed on the first electrode, an absorption layer disposed on the light emitting layer and disposed in the first sub-pixel, and a second electrode disposed on the light emitting layer, wherein the absorption layer disposed in the first sub-pixel is disposed under the second electrode.

### CROSS-REFERENCE TO RELATED APPLICATIONS

This application claims the benefit of the Korean Patent Application No. 10-2024-0029868 filed on Feb. 29, 2024, which is hereby incorporated by reference as if fully set forth herein.

### BACKGROUND

### Technical Field

The present disclosure relates to a display device.

### Description of the Related Art

As an information society develops, demands for a display device for displaying an image are increasing in various forms. Accordingly, various display devices such as a liquid crystal display (LCD), a plasma display (PDP), and an organic light emitting display (OLED) have recently been used.

Among the display devices, the organic light emitting display device is a self-emission type and has excellent viewing angle and contrast ratio compared to the liquid crystal display (LCD). In addition, since a separate backlight is not required, light weight and thinness are possible, and power consumption is advantageous. Furthermore, the organic light emitting display device has advantages of being able to drive a DC low voltage, a fast response speed, and particularly low manufacturing cost.

An organic light emitting display device has a structure in which an organic light emitting device including a light emitting layer is provided between a cathode for injecting electrons and an anode for injecting holes. An organic light emitting display device is a display device using the principle that when electrons generated from a cathode and holes generated from an anode are injected into an emission layer, the injected electrons and holes are combined to generate excitons, and the generated excitons fall from an excited state to a ground state and emit light.

On the other hand, various attempts are being made to improve the user's visual sense when external light entering the display device is reflected by wiring or electrodes provided inside the display device and emitted again.

### BRIEF SUMMARY

The present disclosure has been made in view of the various technical problems in the related art including the above-identified problems. Various embodiments of the present disclosure provide a display device that reduces or minimizes the reflection and emission of external light from the outside into the display device by having an absorption part that absorbs external light in the first sub-pixel that emits white light.

In accordance with an aspect of the present disclosure, the above and other objects can be accomplished by the provision of a display device comprising a substrate including a first sub-pixel and a second sub-pixel a first electrode disposed on the substrate and disposed on each of the first sub-pixel and the second sub-pixel, a light emitting layer disposed on the first electrode, an absorption layer disposed on the light emitting layer and disposed in the first sub-pixel, and a second electrode disposed on the light emitting layer, wherein the absorption layer disposed in the first sub-pixel is disposed under the second electrode.

Furthermore, the above and other objects can be accomplished by the provision of a display device comprising a substrate including a first sub-pixel emitting white light and a second sub-pixel emitting different color from the first sub-pixel, an absorption layer overlapping at least a portion of the first sub-pixel, and a reflective layer disposed to cover the absorption layer, wherein the reflective layer overlaps the first sub-pixel and the second sub-pixel.

Furthermore, the above and other objects can be accomplished by the provision of a display device comprising a substrate including a first sub-pixel and a second sub-pixel, a first electrode disposed on the substrate and disposed on each of the first sub-pixel and the second sub-pixel, a light emitting layer disposed on the first electrode, a second electrode disposed on the light emitting layer and concavely disposed in an area between the first sub-pixel and the second sub-pixel, and an absorption layer disposed between the first sub-pixel and the second sub-pixel, wherein the absorption layer is disposed below the second electrode in a region between the first sub-pixel and the second sub-pixel.

### BRIEF DESCRIPTION OF THE SEVERAL VIEWS OF THE DRAWINGS

The above and other objects, features and other advantages of the present disclosure will be more clearly understood from the following detailed description taken in conjunction with the accompanying drawings, in which:

FIG. 1 is a perspective view schematically illustrating a display device according to an embodiment of the present disclosure.

FIG. 2 is a schematic plan view of a display device according to an embodiment of the present disclosure.

FIG. 3 is a plan view of a display device according to an embodiment of the present disclosure. In this case, FIG. 3 is an enlarged view of an area A of FIG. 2.

FIG. 4 is a cross-sectional view of a display device according to an embodiment of the present disclosure. In this case, FIG. 4 corresponds to the cross-section I-I′ of FIG. 3.

FIG. 5 is a graph showing the intensity of light transmitted for each wavelength band of a display device according to an embodiment and a comparative example of the present disclosure, and a graph showing the transmittance for each wavelength band of a second color filter provided in a display device according to an embodiment of the present disclosure.

FIG. 6 is a graph showing external light transmittance for each wavelength band of a display device according to an embodiment and a comparative example of the present disclosure.

FIGS. 7A to 7C are cross-sectional views illustrating a process of manufacturing a display device according to an embodiment of the present disclosure. In this case, FIGS. 7A to 7C relate to a cross-section I-I′ of FIG. 3.

FIG. 8 is a plan view of a display device according to another embodiment of the present disclosure. In this case, FIG. 8 is an enlarged view of an area A of FIG. 2.

FIG. 9 is a cross-sectional view of a display device according to another embodiment of the present disclosure. In this case, FIG. 9 corresponds to the cross-section II-II′ of FIG. 8.

FIG. 10 is a plan view of a display device according to another embodiment of the present disclosure. In this case, FIG. 10 is an enlarged view of an area A of FIG. 2.

FIG. 11 is a cross-sectional view of a display device according to another embodiment of the present disclosure. In this case, FIG. 11 corresponds to the cross-section III-III′ of FIG. 10.

FIG. 12 is a plan view of a display device according to another embodiment of the present disclosure. In this case, FIG. 12 is an enlarged view of an area A of FIG. 2.

FIG. 13 is a cross-sectional view of a display device according to another embodiment of the present disclosure. In this case, FIG. 13 corresponds to the cross-section IV-IV′ of FIG. 12.

### DETAILED DESCRIPTION

Advantages and features of the present disclosure, and implementation methods thereof will be clarified through the following embodiments, described with reference to the accompanying drawings. The present disclosure may, however, be embodied in different forms and should not be construed as being limited to the embodiments set forth herein. Rather, these embodiments are provided so that this disclosure will be thorough and complete, and will fully convey the scope of the present disclosure to those skilled in the art. Further, the present disclosure is only defined by the scope of the claims.

The shapes, sizes, dimensions (e.g., length, width, height, thickness, radius, diameter, area, etc.), ratios, angles, and numbers disclosed in the drawings for describing embodiments of the present disclosure are merely examples, and thus the present disclosure is not limited to the illustrated details.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout. In the following description, when the detailed description of the relevant known function or configuration is determined to unnecessarily obscure the important point of the present disclosure, the detailed description will be omitted.

In the case in which “comprise,” “have,” and “include” described in the present specification are used, another part may also be present unless “only” is used. The terms in a singular form may include plural forms unless noted to the contrary.

In construing an element, the element is construed as including an error region although there is no explicit description thereof.

In describing a positional relationship, for example, when the positional order is described as “on,” “above,” “below,” “beneath”, and “next,” the case of no contact therebetween may be included, unless “just” or “direct” is used.

If it is mentioned that a first element is positioned “on” a second element, it does not mean that the first element is essentially positioned above the second element in the figure. The upper part and the lower part of an object concerned may be changed depending on the orientation of the object. Consequently, the case in which a first element is positioned “on” a second element includes the case in which the first element is positioned “below” the second element as well as the case in which the first element is positioned “above” the second element in the figure or in an actual configuration.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc., may be used herein to describe various elements, these elements should not be limited by these terms. These terms are only used to distinguish one element from another. For example, a first element could be termed a second element, and, similarly, a second element could be termed a first element.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various embodiments of the present disclosure may be partially or overall coupled to or combined with each other, and may be variously inter-operated with each other and driven technically The embodiments of the present disclosure may be carried out independently from each other, or may be carried out together in a co-dependent relationship.

In the drawings, the same or similar elements are denoted by the same reference numerals even though they are depicted in different drawings.

In the embodiments of the present disclosure, a source electrode and a drain electrode are distinguished from each other, for convenience of explanation. However, the source electrode and the drain electrode are used interchangeably. Thus, the source electrode may be the drain electrode, and the drain electrode may be the source electrode. Also, the source electrode in any one embodiment of the present disclosure may be the drain electrode in another embodiment of the present disclosure, and the drain electrode in any one embodiment of the present disclosure may be the source electrode in another embodiment of the present disclosure.

In one or more embodiments of the present disclosure, for convenience of explanation, a source region is distinguished from a source electrode, and a drain region is distinguished from a drain electrode. However, embodiments of the present disclosure are not limited to this structure. For example, a source region may be a source electrode, and a drain region may be a drain electrode. Also, a source region may be a drain electrode, and a drain region may be a source electrode.

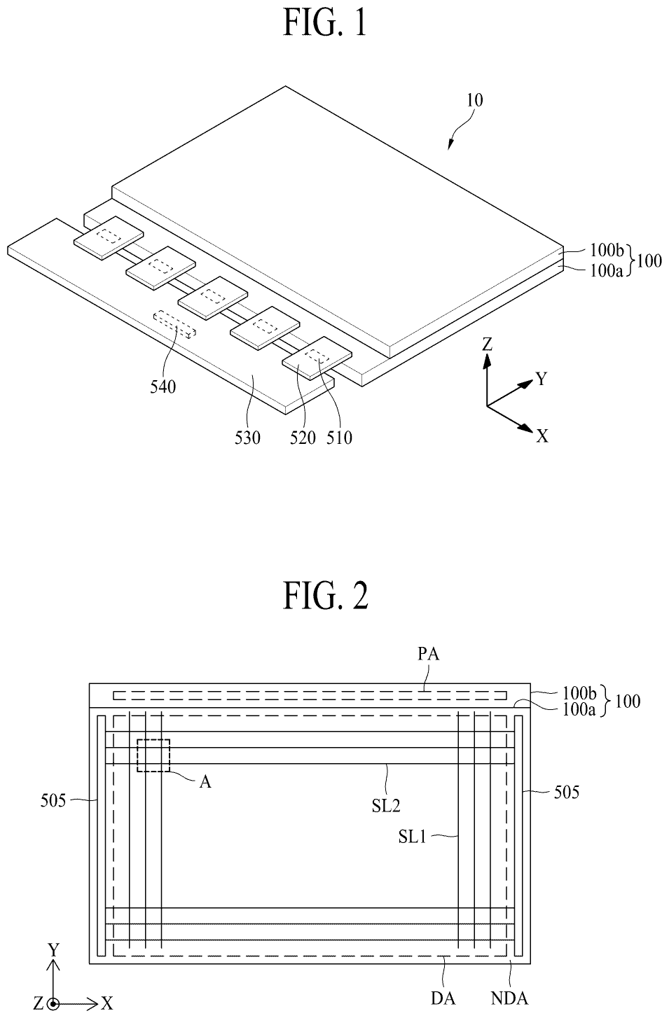

FIG. 1 is a perspective view schematically illustrating a display device according to an embodiment of the present disclosure, and FIG. 2 is a schematic plan view of a display device according to an embodiment of the present disclosure.

Hereinafter, the X axis represents a direction parallel to the gate line, the Y axis represents a direction parallel to the data line, and the Z axis represents the height direction of the display device 10.

Although the display device 10 according to an embodiment of the present disclosure is mainly described as an organic light emitting display, it may be implemented as a liquid crystal display LCD, a plasma display panel PDP, a quantum dot light emitting display QLED, or an electrophoretic display.

Referring to FIGS. 1 and 2, a display device 10 according to an embodiment of the present disclosure includes a display panel 100, a source drive integrated circuit (hereinafter referred to as an “IC”) 510, a flexible film 520, a circuit board 530, and a timing controller 540.

The display panel 100 may include the first substrate 100a and the second substrate 100b facing each other. The second substrate 100b may be an encapsulation substrate. The first substrate 100a may be a plastic film, a glass substrate of a silicon wafer substrate formed by using a semiconductor process. The second substrate 100b may be a plastic film, a glass substrate, or an encapsulation film. The first substrate 100a and the second substrate 100b may be made of a transparent material.

The display panel 100 may be divided into a display area DA in which pixels are formed to display an image and a non-display area NDA in which an image is not displayed.

First signal lines SL1, second signal lines SL2, and pixels may be provided in the display area DA, and a pad area PA in which pads are disposed and at least one gate driver 505 may be provided in the non-display area NDA.

The first signal lines SL1 may extend in a first direction, for example a Y axis direction, and may cross the second signal lines SL2 in the display area DA. The second signal lines SL2 may extend in a second direction, for example an X axis direction in the display area DA. The pixels are provided in an area in which the first signal line SL1 is provided or an area in which the first signal line SL1 and the second signal line SL2 intersect, and emit predetermined light to display an image.

The first signal lines SL1 may include, for example, at least one of a common power line, a reference line, data lines, and a pixel power line.

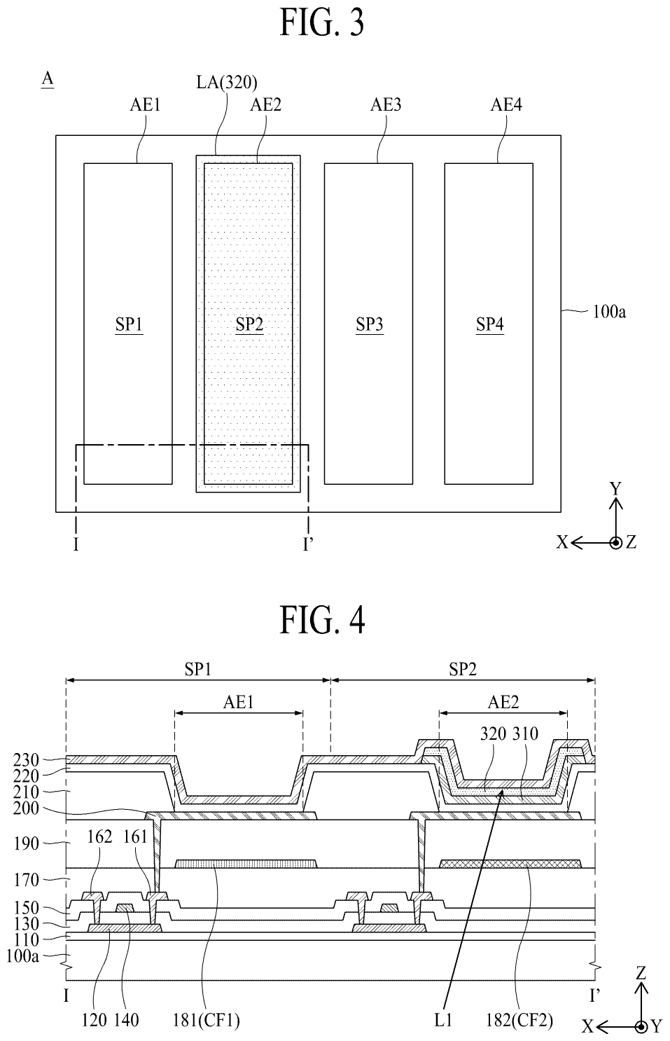

The pixel power line may supply a first power to the driving thin film transistor of each of a plurality of sub-pixels (see SP1, SP2, SP3, and SP4 of FIG. 3). The common power line may supply a second power to a cathode electrode of a plurality of sub-pixels (See SP1, SP2, SP3, and SP4 of FIG. 3). In this case, the second power may be a common power source that is commonly supplied to a plurality of sub-pixels (See SP1, SP2, SP3, and SP4 of FIG. 3).

The reference line may supply an initialization voltage (or a reference voltage) to the driving thin film transistor of each of the plurality of sub-pixels (Sec SP1, SP2, SP3, and SP4 of FIG. 3). Each of the data lines may supply a data voltage to a plurality of sub-pixels (see SP1, SP2, SP3, and SP4 of FIG. 3).

The second signal line SL2 may extend in a second direction (e.g., an X-axis direction), and may include, for example, a gate line (not shown). The gate line (not shown) may supply a gate signal to a plurality of sub-pixels (see SP1, SP2, SP3, and SP4 of FIG. 3).

The source drive IC 510 receives digital video data and a source control signal from the timing controller 540. The source drive IC 510 converts digital video data into analog data voltages according to a source control signal and supplies the converted analog data voltages to the data lines. When the source drive IC 510 is manufactured as a driving chip, the source drive IC 510 may be mounted on the flexible film 520 in a chip on film (COF) or chip on plastic (COP) manner.

Wirings connecting pads and the source drive IC 510 and wirings connecting pads and wirings of the circuit board 530 may be formed in the flexible film 520. The flexible film 520 is attached onto the pads using an anisotropic conducting film, and thus the wirings of the pads and the flexible film 520 may be connected to each other.

The circuit board 530 may be attached to the flexible films 520. A plurality of circuits implemented with driving chips may be mounted on the circuit board 530. For example, the timing controller 540 may be mounted on the circuit board 530. The circuit board 530 may be a printed circuit board or a flexible printed circuit board.

The timing controller 540 receives digital video data and a timing signal from an external system board (not shown). The timing controller 540 generates a gate control signal for controlling the operation timing of the gate driver 505 and a source control signal for controlling the source drive ICs 510, based on the timing signal. The timing controller 540 supplies the gate control signal to the gate driver 505, and supplies the source control signal to the source drive ICs 510.

FIG. 3 is a plan view of a display device according to an embodiment of the present disclosure. In this case, FIG. 3 is an enlarged view of an area A of FIG. 2.

As shown in FIG. 3, the display device according to an embodiment of the present disclosure may include a first sub-pixel SP1, a second sub-pixel SP2, a third sub-pixel SP3, and a fourth sub-pixel SP4. Specifically, the display device according to an embodiment of the present disclosure may include a first sub-pixel SP1, a second sub-pixel SP2, a third sub-pixel SP3, and a fourth sub-pixel SP4 provided on the first substrate 100a.

The first sub-pixel SP1, the second sub-pixel SP2, the third sub-pixel SP3, and the fourth sub-pixel SP4 may be arranged along the second direction (X direction).

Meanwhile, in the present disclosure, for convenience of description, it has been described that the first sub-pixel SP1, the second sub-pixel SP2, the third sub-pixel SP3, and the fourth sub-pixel SP4 emit light of red (R), white (W), blue (B), and green (G), respectively, but the present disclosure is not limited thereto, and the light emitted by the first sub-pixel SP1 to the fourth sub-pixel SP4 may vary according to the level of technology in the art.

Also, although the first to fourth sub-pixels SP1 to SP4 are all formed in the same shape and size for convenience of description, the present disclosure is not limited thereto. For example, the sizes of the first to fourth sub-pixels SP1 to SP4 may be variously adjusted according to the efficiency of light of red (R), white (W), blue (B), and green (G), and may be formed in a shape other than a stripe shape.

First electrodes including portions AE1, AE2, AE3, and AE4 exposed without being covered by bank may be patterned to correspond to each sub-pixel in the first to fourth sub-pixel SP1 to SP4. Each of the first electrodes including the portions AE1, AE2, AE3, and AE4 is formed to be spaced apart from each other, and a light emitting area in which light is emitted by the first electrodes including the portions AE1, AE2, AE3, and AE4 may be defined.

According to an embodiment of the present disclosure, an absorption layer LA(320) may be formed in the second sub-pixel SP2 emitting white W to correspond to the second sub-pixel SP2. The absorption layer LA(320) may be provided only in the second sub-pixel SP2, and may not be provided in the first sub-pixel SP1, the third sub-pixel SP3, and the fourth sub-pixel SP4.

Since the absorption layer LA(320) is formed in the second sub-pixel SP2 emitting white (W), light flowing into the second sub-pixel SP2 from the lower surface of the first substrate 100a is absorbed by the absorption layer LA(320) to reduce the reflectance of the second sub-pixel SP2, thereby improving the user's visual sense. Meanwhile, the related description will be made in more detail with reference to FIG. 4.

The absorption layer LA(320) may overlap the portion AE2 of the first electrode of the second sub-pixel SP2. For example, the absorption layer LA(320) may be provided to overlap the entire region of the portion AE2 of the first electrode of the second sub-pixel SP2. In some embodiments, the absorption layer 320 overlaps the portion AE2 of the first electrode when seen from a plan view as shown in FIG. 3.

FIG. 4 is a cross-sectional view of a display device according to an embodiment of the present disclosure. In this case, FIG. 4 corresponds to the cross-section I-I′ of FIG. 3.

As shown in FIG. 4, a display device according to an embodiment of the present disclosure includes a first substrate 100a, a buffer layer 110, an active layer 120, a gate insulating layer 130, a gate electrode 140, an interlayer insulating layer 150, a source electrode 161, a drain electrode 162, a first planarization layer 170, a second planarization layer 190, a first color filter 181(CF1), a second color filter 182(CF2), a first electrode 200, a bank 210, a light emitting layer 220, a second electrode 230, a metal buffer layer 310, and an absorption layer 320.

The first substrate 100a may be made of glass or plastic. Particularly, the first substrate 100a may be made of transparent plastic having flexible characteristics, for example, polyimide. When the polyimide is used as the first substrate 100a, considering that a high-temperature deposition process is performed on the first substrate 100a, heat-resistant polyimide capable of withstanding high temperature may be used.

The buffer layer 110 may be formed on the first substrate 100a. The buffer layer 110 may protect the active layer 120 by blocking air and moisture. The buffer layer 110 may be made of an inorganic insulating material such as silicon oxide, silicon nitride, or metal oxide, but is not limited thereto and may be made of an organic insulating material.

The active layer 120 may be formed on the buffer layer 110. The active layer 120 may include any one of a semiconductor material, for example, amorphous silicon, polycrystalline silicon, and oxide semiconductor material.

Although not specifically illustrated, the active layer 120 includes a channel portion that overlaps the gate electrode 140 to maintain semiconductor characteristics without being conductive in the conductive process, and a first connection portion provided on one side of the channel portion, for example, on the left side, and a second connection provided on another side, for example, on the right side, of the channel portion, and provided with conductive characteristics by the conductive process. In this case, the conductive process may be, for example, a process of performing plasma treatment on a semiconductor material using the gate electrode 140 as a mask, but is not limited thereto. The first connection portion and the second connection portion by the conductive process have excellent conductive characteristics and may serve as an electrode or a wiring.

The gate insulating layer 130 may be formed on the active layer 120. The gate insulating layer 130 may be formed on the entire surface of the first substrate 100a, but the present disclosure is not limited thereto, and a partial region of the gate insulating layer 130 may be patterned so that one end and another end of the gate insulating layer 130 correspond to one end and another end of the gate electrode 140, respectively.

The gate insulating layer 130 may include a silicon nitride film (SiNx) or a silicon oxide film (SiOx), but is not limited thereto. The gate insulating layer 130 may be formed of a single layer or a plurality of layers including an inorganic insulating material and/or an organic insulating material.

The gate electrode 140 may be formed on the gate insulating layer 130.

The gate electrode 140 may include at least one of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti). The gate electrode 140 may have a structure including one metal layer or a multilayer structure including at least two metal layers each having different physical properties.

The interlayer insulating layer 150 may be formed on the gate electrode 140. The interlayer insulating layer 150 insulates between the gate electrode 140 and the source electrode 161 and further insulates between the gate electrode 140 and the drain electrode 162. The interlayer insulating layer 150 may be formed of a single layer or a plurality of layers including an inorganic insulating material and/or an organic insulating material.

A contact hole may be formed in the interlayer insulating layer 150. Accordingly, a portion of the upper surface of the one side of the active layer 120, for example, the first connection portion of the active layer 120 may be exposed by one contact hole, and further, a portion of the upper surface of another side of the active layer 120, for example, the second connection portion of the active layer 120 may be exposed by another contact hole.

The source electrode 161 and the drain electrode 162 may be disposed on the interlayer insulating layer 150.

The source electrode 161 may be electrically connected to one side of the active layer 120 by the contact hole, and the drain electrode 162 may be electrically connected to another side of the active layer 120 by the contact hole.

The source electrode 161 and the drain electrode 162 may be formed of the same material as the gate electrode 140, but are not limited thereto and may be formed of a material according to knowledge in the art.

The first planarization layer 170 may be formed on the interlayer insulating layer 150, the source electrode 161, and the drain electrode 162. The first planarization layer 170 may be formed on the source electrode 161 and the drain electrode 162 to planarize an upper surface of the first planarization layer 170.

A contact hole is provided in the first planarization layer 170, and a portion of the upper surface of the source electrode 161 may be exposed by the contact hole. However, in some cases, a portion of the upper surface of the drain electrode 162 may be exposed by the contact hole.

The first planarization layer 170 may be formed of an organic insulating layer material. The first planarization layer 170 may be formed of, for example, an organic insulating material such as an acrylic resin, an epoxy resin, a phenolic resin, a polyamide resin, or a polyimide resin.

The first color filter 181(CF1) and the second color filter 182(CF2) may be formed on the first planarization layer 170.

The first color filter 181 is provided to correspond to the first sub-pixel SP1. The first color filter 181 may transmit any one light among red (R), green (G), and blue (B). Accordingly, by the first color filter 181, the first sub-pixel SP1 may display any one light among red (R), green (G), and blue (B).

For example, the first color filter 181 may transmit red (R) light. Accordingly, the first sub-pixel SP1 may transmit red (R) light by the first color filter 181. Meanwhile, although not shown in detail, a third color filter for transmitting green (G) light and a fourth color filter for transmitting blue (B) may be formed in regions corresponding to the third sub-pixel SP3 and the fourth sub-pixel SP4, respectively.

The second color filter 182(CF2) may be provided to correspond to the second sub-pixel SP2. More specifically, according to an embodiment of the present disclosure, the second color filter 182 may be provided to correspond to the second sub-pixel SP2 emitting white (W).

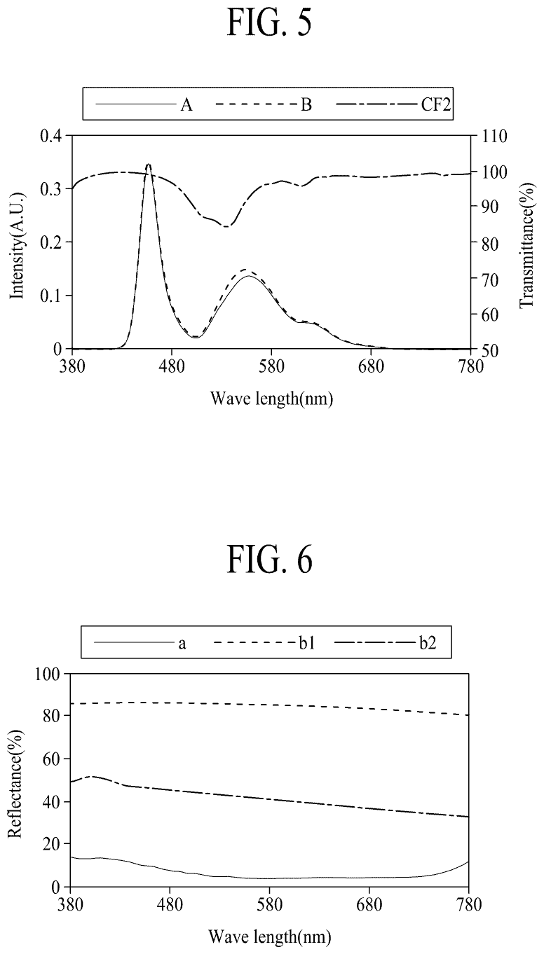

The second color filter 182(CF2) may be provided such that the transmittance of light in a wavelength range equal to or more than 530 nm and less than 570 nm is more than or equal to 85% and less than or equal to 95% of the transmittance of light in a wavelength range equal to or more than 380 nm and less than 530 nm and in a wavelength range equal to or greater than 570 nm and less than 780 nm. By forming in this way, white (W) light emitted from the light emitting layer 220 provided in the second sub-pixel SP2 may be transmitted through the second color filter 182 and emitted to the lower surface of the first substrate 100a, thereby realizing white (W) light having an improved color temperature, and accordingly, the luminance of the white (W) light emitted from the second sub-pixel SP2 may increase. Meanwhile, in this regard, a little more detail will be described with reference to FIG. 5 below.

The second planarization layer 190 may be formed on the first color filter 181 and the second color filter 182. The second planarization layer 190 may be formed on the first color filter 181 and the second color filter 182 to planarize an upper surface of the second planarization layer 190.

A contact hole is provided in the second planarization layer 190, and a portion of the upper surface of the source electrode 161 may be exposed by the contact hole. However, in some cases, a portion of the upper surface of the drain electrode 162 may be exposed by the contact hole.

The second planarization layer 190 may be formed of an organic insulating layer material. The second planarization layer 190 may be formed of, for example, an organic insulating material such as an acrylic resin, an epoxy resin, a phenolic resin, a polyamide resin, or a polyimide resin.

The first electrode 200 may be formed on the second planarization layer 190 and may be electrically connected to the source electrode 161 through the contact hole provided in the first planarization layer 170 and the second planarization layer 190. The first electrode 200 may function as an anode electrode. The first electrode 200 is provided to correspond to the first sub-pixel SP1 and the second sub-pixel SP2, respectively, and the first electrode 200 provided in the first sub-pixel SP1 may correspond to the first anode electrode (see AE1 of FIG. 3) illustrated in FIG. 3, and the second electrode 200 provided in the second sub-pixel SP2 may correspond to the second anode electrode (see AE2 of FIG. 3) illustrated in FIG. 3.

The first electrode 200 may be formed of, for example, a transparent electrode. Therefore, light emitted from the light emitting layer 220 of the first sub-pixel SP1 and the second sub-pixel SP2 may pass through the first electrode 200 and be emitted toward the first substrate 100a. However, the present disclosure is not limited thereto.

The bank 210 may be formed on the first electrode 200. In this case, a partial region of the upper surface of the first electrode 200 exposed without being covered by the bank 210 becomes a light emitting area.

The bank 210 may be formed of an organic layer such as an acrylic resin, an epoxy resin, a phenolic resin, a polyamide resin, or a polyimide resin. Meanwhile, the present disclosure is not limited thereto, and the bank 210 may be, for example, a black bank. When the bank 210 is formed of, for example, a black bank, it may include a light-shielding material that absorbs light.

The light emitting layer 220 may be formed on the first electrode 200. The light emitting layer 220 may be formed of, for example, a white light emitting layer connected to all pixels. When the light emitting layer 220 is formed of a white light emitting layer, the light emitting layer 220 may include, for example, a first stack including a blue light emitting layer, a second stack including a yellow-green light emitting layer, and a charge generation layer provided between the first stack and the second stack, and the light emitting layer 220 may include, for example, a first stack including a blue light emitting layer, a second stack including a yellow-green light emitting layer, for example, a third stack including a blue light emitting layer, a first charge generation layer provided between the first stack and the second stack, and a second charge generation layer provided between the second stack and the third stack, but is not limited thereto.

The second electrode 230 may be formed on the light emitting layer 220. The second electrode 230 may function as a cathode.

The second electrode 230 may be formed, for example, on all surfaces of the bank 210 and the light emitting layer 220. Accordingly, the second electrode 230 may be formed on all surfaces of the first sub-pixel SP1 and the second sub-pixel SP2.

The second electrode 230 may be formed as, for example, a reflective electrode. Therefore, light emitted from the light emitting layer 220 of the first sub-pixel SP1 and the second sub-pixel SP2 may be reflected by the second electrode 230 and may pass through the first electrode 200 to be emitted toward the first substrate 100a. However, the present disclosure is not limited thereto.

According to an embodiment of the present disclosure, the second sub-pixel SP2 may further include a metal buffer layer 310 formed on the light emitting layer 220, and an absorption layer 320 formed on the metal buffer layer 310 and provided below the second electrode 230. By forming as described above, a distance between the first electrode 200 and the second electrode 230 in the second sub-pixel SP2 may be greater than a distance between the first electrode 200 and the second electrode 230 in the first sub-pixel SP1. In this case, the distance between the first electrode 200 and the second electrode 230 may be defined as the shortest distance from the upper surface of the first electrode 200 to the lower surface of the second electrode 230.

The metal buffer layer 310 is formed on the light emitting layer 220 in the second sub-pixel SP2, and in detail, the metal buffer layer 310 may overlap the entire upper surface of the first electrode 200 exposed by the bank 210 in the second sub-pixel SP2. In more detail, the metal buffer layer 310 may be formed to overlap one sidewall of the bank 210, for example, the right sidewall and another sidewall of the bank 210, for example, the left sidewall of the bank 210, which partition the second sub-pixel SP2.

The metal buffer layer 310 may include the same material as the second electrode 230. The metal buffer layer 310 may include, for example, aluminum (Al), but is not limited thereto, and may include various materials according to the level of the art. In one or more embodiments, the metal buffer layer 310 is a distinct and separate structure from the second electrode 230 but may include the same material as the second electrode 230.

The metal buffer layer 310 may allow electrons to be smoothly injected from the second electrode 230 into the light emitting layer 220 according to the energy level of the light emitting layer 220 and the absorption layer 320.

The absorption layer 320 may be formed on the metal buffer layer 310 in the second sub-pixel SP2. Specifically, the absorption layer 320 may overlap the entire upper surface of the first electrode 200 exposed by the bank 210 in the second sub-pixel SP2. More specifically, the absorption layer 320 may be formed to overlap one sidewall of the bank 210, for example, a right sidewall and another sidewall of the bank 210, for example, a left sidewall of the bank 210, which partition the second sub-pixel SP2.

According to an embodiment of the present disclosure, since the metal buffer layer 310 and the absorption layer 320 are provided to cover the entire upper surface of the first electrode 200 exposed from the bank 210, even if the external light L1 flowing from the outside of the first substrate 100a passes through the first electrode 200 of the second sub-pixel SP2, it is completely absorbed or blocked by the absorption layer 320 to prevent or minimize the external light L1 from being reflected by the second electrode 230.

In addition, by lowering the reflectance of the second sub-pixel SP2 emitting white (W), it is not necessary to attach a separate film, for example, a polarizing film, to a display device (see 10 of FIG. 1) to prevent reflection of external light. Since a separate film for preventing reflection of external light is not attached, high luminance and excellent contrast ratio of each of the sub-pixels SP1 to SP4 can be implemented.

The absorption layer 320 may include an oxygen-deficient metal oxide. In this case, the oxygen-deficient metal oxide refers to a compound in which the equivalent of an oxygen atom is lower than the equivalent of a metal atom with respect to the equivalent of a metal atom to an oxygen atom for forming a neutral metal oxide. For example, in order for metal ions (Ma+) and oxygen ions (O2−) to form a compound and become neutral, metal atoms (M) and oxygen atoms (O) must react with an equivalent of 2:a. In the case of an oxygen-deficient metal oxide, it refers to a compound in which metal atoms (M) and oxygen atoms (O) are reacted with an equivalent of 2:b (in this case, b is an integer greater than a and greater than 0). The absorption layer 320 may include, for example, an oxygen-deficient aluminum oxide (Al2Ox, in this case, x is greater than 0 and less than 3) or an oxygen-deficient zinc oxide (ZnOy, in this case, y is greater than 0 and less than 1), but is not limited thereto.

According to an embodiment of the present disclosure, even if the external light L1 introduced from the outside of the first substrate 100a passes through the first electrode 200 of the second sub-pixel SP2, the external light L1 may not reach the second electrode 230 and may be absorbed by the absorption layer 320, thereby preventing the external light L1 introduced from the outside of the first substrate 100a from being reflected. Accordingly, the reflectance of external light in the second sub-pixel SP2 emitting white (W) may be lowered, thereby improving the user's visibility.

Meanwhile, although not specifically illustrated, an encapsulation layer may be provided on the second electrode 230, and a second substrate (see 110b in FIG. 2) may be formed on the encapsulation layer. The encapsulation layer may include, for example, a first encapsulation layer, a second encapsulation layer, and a third encapsulation layer. The first encapsulation layer to the third encapsulation layer may be sequentially stacked on the second electrode 230, the first encapsulation layer and the third encapsulation layer may be formed of an inorganic layer including an inorganic material, and the second encapsulation layer may be formed of an organic layer including an organic material.

As illustrated in FIG. 4, the absorption layer 320 is present in the second sub-pixel SP2 but is not present in the first sub-pixel SP1 adjacent to the second sub-pixel SP2. Here, the figure illustrates that the light emitting layer 220 continuously and contiguously extends from the first sub-pixel SP1 to the second sub-pixel SP2. Similarly, the second electrode 230 continuously and contiguously extends from the first sub-pixel SP1 to the second sub-pixel SP2.

Here, the second sub-pixel SP2 includes a metal buffer layer 310 between the light emitting layer 220 and the absorption layer 320. In some embodiments, the metal buffer layer 310 directly contacts a bottom surface of the absorption layer 320 and an upper surface of the light emitting layer 220.

As illustrated, in some embodiments, the bank 210 has a trapezoidal cross-section and has two side surfaces and an upper surface between the two side surfaces. The metal buffer layer 310 may extend such that the metal buffer layer 310 covers the side surface of the bank 210 and at least a portion of the upper surface of the bank 210. Similarly, the absorption layer 320 is disposed on the metal buffer layer 310 and extends such that the absorption layer 320 covers the side surface of the bank 210 and at least a portion of the upper surface of the bank 210. The absorption layer 320 overlaps the metal buffer layer 310 from a plan view.

In some embodiments, the absorption layer 320 is on and spaced apart from the light emitting layer 220. In the first sub-pixel SP1 where the absorption layer 320 is not present, the light emitting layer 220 is between and directly contacts the first electrode 200 and the second electrode 230. On the other hand, in the second sub-pixel SP2 where the absorption layer 320 is present, the absorption layer 320 does not directly contact the light emitting layer 220.

FIG. 5 is a graph showing the intensity of light transmitted for each wavelength band of a display device according to an embodiment and a comparative example of the present disclosure, and a graph showing the transmittance for each wavelength band of a second color filter provided in a display device according to an embodiment of the present disclosure.

As shown in FIG. 5, A represents intensity (%) for each wavelength band of light emitted through the second color filter CF2 in the second sub-pixel SP2 of the display device according to an embodiment of the present disclosure, and B represents intensity for each wavelength band of light emitted from the sub-pixel of the display device according to the comparative example. In this case, unlike an embodiment of the present disclosure, the display device B according to the comparative example is not provided with the second color filter CF2. Furthermore, C represents transmittance for each wavelength band of the second color filter CF2.

According to an embodiment of the present disclosure, the second color filter CF2 may be provided such that the transmittance of light in a wavelength range equal to or more than 530 nm and less than 570 nm is more than or equal to 85% and less than or equal to 95% of the transmittance of light in a wavelength range equal to or more than 380 nm and less than 530 nm and in a wavelength range equal to or greater than 570 nm and less than 780 nm. By forming in this way, in the case of Example (A), the intensity (%) of the wavelength range of 530 nm or more and 570 nm or less is slightly lower than that of Comparative Example (B).

Table 1 below relates to emission efficiency, color coordinates (Wx and Wy), color temperature, luminance, and reflectance of sub-pixels emitting white (W), with respect to embodiments (A) and comparative example (B). In this case, the luminance (%) of embodiment (A) relates to a relative ratio of the luminance (%) of comparative example (B), and the reflectance (%) is relative to the ratio of the light reflected to the outside of the sub-pixel (see L1 in FIG. 4) that emits white (W).

TABLE 1

| | | Comparative |
|---|---|---|
| | Example (A) | Example (B) |
| Luminous Efficiency (Cd/A) | 58.14 | 63.05 |
| Color Coordinates (Wx, Wy) | (0.284, 0.294) | (0.285, 0.306) |
| Color Temperature (K) | 9295 | 8817 |
| Luminance (Nit) | 455 | 373 |
| Luminance (%) | 121.9 | 100 |
| Reflection Rate (%) | 61.2 | 74.6 |

While the efficiency and color coordinates of the sub-pixel (see the second sub-pixel SP2 in FIG. 4) emitting white (W) according to the embodiment (A) are 58.14 Cd/A, 0.284, and 0.294, respectively, and the efficiency and color coordinates of the sub-pixel emitting white (W) according to the comparative example (B) are 63.05 Cd/A, 0.285, and 0.306, which means that it may be seen that the efficiency and color coordinates of the sub-pixel emitting white (A) and the comparative example (B) have similar efficiency and color coordinates, the color temperature and luminance of the sub-pixel (refer to the second sub-pixel SP2 in FIG. 4) emitting white W according to embodiment A are 9295K and 455 Nit, respectively, higher than the color temperature and luminance of the sub-pixel emitting white W according to comparative example B, and the reflectance of embodiment A is 61.2%, lower than the reflectance of comparative example B of 74.6%.

FIG. 6 is a graph showing external light transmittance for each wavelength band in a sub-pixel emitting white (W) provided in a display device according to an embodiment and a comparative example of the present disclosure. In this case, the solid line a is a graph showing the external light transmittance for each wavelength band of a sub-pixel (refer to the second sub-pixel SP2 of FIG. 4) emitting the white W in the display device according to an embodiment of the present disclosure, the dotted line b1 is a graph showing the external light transmittance for each wavelength band of the sub-pixel emitting the white W in the display device according to Comparative Example 1-1, and the one-dotted line b2 is a graph showing the external light transmittance for each wavelength band of the sub-pixel emitting the white W in the display device according to Comparative Example 1-2. Furthermore, Comparative Example 1-1(b1) relates to a case in which a second electrode is formed on a light emitting layer without a metal buffer layer and an absorption layer, and Comparative Example 1-2(b2) relates to a case in which a metal buffer layer, an organic layer, and a second electrode are sequentially formed on a light emitting layer.

Furthermore, Table 2 below is a table measuring reflectance of each wavelength band of Example (a), Comparative Examples 1-1(b1), and Comparative Examples 1-2(b2).

TABLE 2

| | Reflection Rate (%) | | |
|---|---|---|---|
| Wavelength | Example | Comparative | Comparative |
| (nm) | (a) | Example 1-1(b1) | Example 1-2(b2) |
| 450 | 10.6 | 86.5 | 46.6 |
| 550 | 4.4 | 85.9 | 42.2 |
| 650 | 4.3 | 84.5 | 38.1 |

In the case of embodiment (a), it may be seen that the reflectance in the wavelength ranges of 450 nm, 550 nm, and 650 nm are lower than those of Comparative Examples 1-1(b1) and 1-2(b2), respectively, as 10.6%, 4.4%, and 4.3%. In addition, as may be seen from FIG. 6, the reflectance percentage of embodiment (a) is lower than that of Comparative Examples 1-1(b1) and 1-2(b2) in the wavelength range of 380 nm to 780 nm.

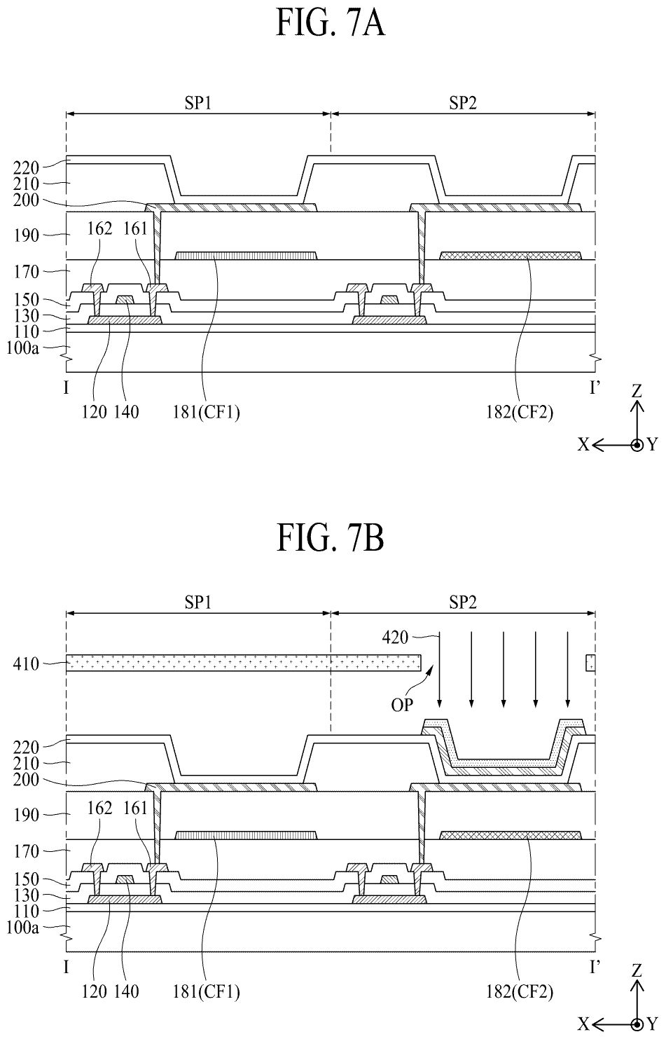

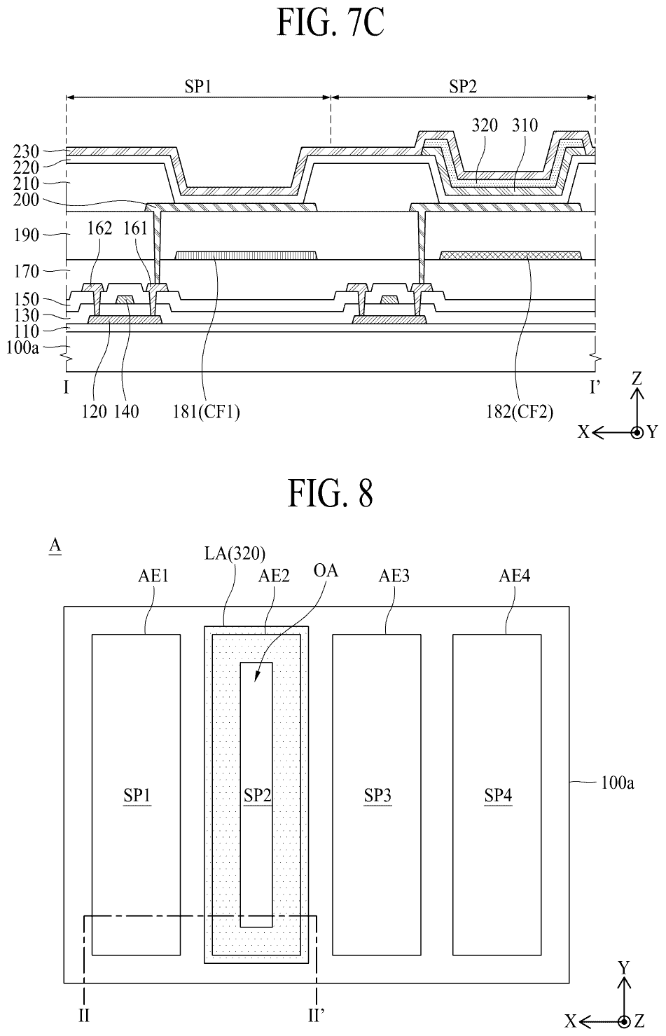

FIGS. 7A to 7C are cross-sectional views illustrating a process of manufacturing a display device according to an embodiment of the present disclosure. In this case, FIGS. 7A to 7C relate to a cross-section I-I′ of FIG. 3. Meanwhile, the manufacturing process of FIGS. 7A to 7C relates to a display device according to an embodiment of FIG. 4, and the same reference numerals are assigned to the same components, and repeated descriptions are omitted.

First, as shown in FIG. 7A, a buffer layer 110, an active layer 120, a gate insulating layer 130, a gate electrode 140, an interlayer insulating layer 150, a source electrode 161 and a drain electrode 162, a first planarization layer 170, a first color filter 181, a second color filter 182, a second planarization layer 190, a first electrode 200, a bank 210, and a light emitting layer 220 are sequentially formed on the first substrate 100a. In this case, the first color filter 181, the second color filter 182, and the first electrode 200 may be patterned to correspond to the first sub-pixel SP1 and the second sub-pixel SP2, respectively.

Next, as shown in FIG. 7B, the mask 410 is positioned on the first sub-pixel SP1 and the second sub-pixel SP2. In this case, in the mask 410, an open pattern OP is formed in a region corresponding to the second sub-pixel SP2. The mask 410 may be, for example, a fine metal mask (FMM), but is not limited thereto.

According to an embodiment of the present disclosure, while the deposition material 420 is deposited in a partial area of the second sub-pixel SP2 exposed by the open pattern OP of the mask 410, the metal buffer layer 310 and the absorption layer 320 may be sequentially formed on the light emitting layer 220 of the second sub-pixel SP2.

In this case, the deposition material 420 for forming the metal buffer layer 310 and the deposition material 420 for forming the absorption layer 320 may be different from each other. For example, the deposition material 420 for forming the metal buffer layer 310 may be aluminum (Al), and the deposition material 420 for forming the absorption layer 320 may be a mixture of silicon monoxide (SiO) and aluminum (Al) at an atomic ratio (At %) of 1:5, respectively, but is not limited thereto.

When the deposition material 420 for forming the absorption layer 320 is selected as silicon monoxide (SiO) and aluminum (Al) in an atomic ratio (At %) of 1:5, the absorption layer 320 may include, for example, an oxygen-deficient aluminum oxide (Al2Ox, in this case, x is a number greater than 0 and less than 3).

Finally, as shown in FIG. 7C, a mask (see 410 of FIG. 7B) may be removed and a second electrode 230 may be formed on the front surfaces of the first sub-pixel SP1 and the second sub-pixel SP2.

FIG. 8 is a plan view of a display device according to another embodiment of the present disclosure. In this case, FIG. 8 is an enlarged view of an area A of FIG. 2. Meanwhile, an embodiment of FIG. 8 is the same as an embodiment of FIG. 3 except for the configuration of the absorption layer, and thus different configurations will be mainly described below.

As shown in FIG. 8, the display device according to another embodiment of the present disclosure may include a first sub-pixel SP1, a second sub-pixel SP2, a third sub-pixel SP3, and a fourth sub-pixel SP4. Specifically, the display device according to another embodiment of the present disclosure may include a first sub-pixel SP1, a second sub-pixel SP2, a third sub-pixel SP3, and a fourth sub-pixel SP4 provided on the first substrate 100a.

According to another embodiment of the present disclosure, an absorption layer LA(320) may be formed in the second sub-pixel SP2 emitting white W to correspond to the second sub-pixel SP2. The absorption layer LA(320) may be provided only in the second sub-pixel SP2, and may not be provided in the first sub-pixel SP1, the third sub-pixel SP3, and the fourth sub-pixel SP4.

According to another embodiment of the present disclosure, unlike the absorption layer LA(320) formed to cover the entire surface of the second sub-pixel SP2 in the embodiment of FIG. 3, the absorption layer LA(320) may be formed to cover at least a portion of the second sub-pixel SP2 without covering the entire surface of the second sub-pixel SP2. Specifically, an opening area OA may be provided in a partial area of the absorption layer LA(320), and a portion of the upper surface of the second anode electrode AE2 may be exposed to the outside through the opening area OA. For example, the opening area OA may be formed in the central portion of the absorption layer LA(320) to expose the central portion of the second sub-pixel SP2. By forming in this way, it is possible to reduce the reflectance in the second sub-pixel SP2 and achieve high luminance.

According to another embodiment of the present disclosure, since the opening area OA is formed in a partial area of the absorption layer LA(320), the light efficiency and reflectance of the second sub-pixel SP2 emitting white (W) may be optimized, thereby realizing a white (W) sub-pixel having high light efficiency and low reflectance. Specifically, by adjusting the size of the opening area OA formed in a partial area of the absorption layer LA(320), the area of the absorption layer LA(320) covering the second sub-pixel SP2 emitting white (W) may be adjusted, and by adjusting the area of the absorption layer LA(320), the light efficiency and reflectance in the second sub-pixel SP2 emitting white (W) may be adjusted. Meanwhile, the light efficiency and reflectance in the second sub-pixel SP2 according to the area of the absorption layer LA(320) will be described in more detail through Table 3 below.

Table 3 below shows the efficiency, reflectance, and luminance of the white (W) sub-pixels according to the area (%) of the absorption layers of Comparative Example 2-1 and Examples 2-1 to 2-10, which are sub-pixels emitting white (W). In this case, the area (%) of the absorption layer may be defined as the ratio (%) of the area of the absorption layer LA(320) covering the portion AE2 of the second anode electrode to the total area of the portion AE2 of the second anode electrode, and the area (%) of the absorption layer was increased by 10% toward Comparative Example 2-1 and Examples 2-1 to 2-10, and the simulation was performed.

TABLE 3

| | Comparative | | | | | | | | | | |
|---|---|---|---|---|---|---|---|---|---|---|---|
| | example | Example | Example | Example | Example | Example | Example | Example | Example | Example | Example |
| | 2-1 | 2-1 | 2-2 | 2-3 | 2-4 | 2-5 | 2-6 | 2-7 | 2-8 | 2-9 | 2-10 |
| An area of | 0 | 10 | 20 | 30 | 40 | 50 | 60 | 70 | 80 | 90 | 100 |
| the | | | | | | | | | | | |
| absorption | | | | | | | | | | | |
| layer (%) | | | | | | | | | | | |
| Luminous | 54.16 | 54.07 | 53.97 | 53.88 | 53.78 | 53.69 | 53.59 | 53.5 | 53.4 | 53.31 | 29.07 |
| Efficiency | | | | | | | | | | | |
| (Cd/A) | | | | | | | | | | | |
| Reflection | 64 | 58 | 52.1 | 46.1 | 40.1 | 34.2 | 28.2 | 22.2 | 16.3 | 10.3 | 3.8 |
| Rate (%) | | | | | | | | | | | |
| Luminance | 388 | 385 | 382 | 379 | 377 | 376 | 375 | 376 | 352 | 327 | 301 |
| (Nit) | | | | | | | | | | | |
| Luminance | 100 | 99.2 | 98.4 | 97.8 | 97.2 | 96.9 | 96.7 | 96.9 | 90.7 | 84.2 | 77.7 |
| (%) | | | | | | | | | | | |

As can be seen from Table 3, while the reflectance of the second sub-pixel SP2 emitting white (W) is high at 64.0%, in the case of Comparative Example 2-1 in which the absorption layer LA(320) is not provided, in the case of Examples 2-1 to 2-10 in which the absorption layer LA(320) is provided, the reflectance gradually decreases. On the other hand, when the area of the absorption layer LA(320) exceeds 70%, the luminance of the second sub-pixel SP2 emitting white (W) may decrease. According to another embodiment of the present disclosure, the area of the absorption layer LA(320) with respect to the portion AE2 of the second anode electrode may be 20% or more and 70% or less. When the area of the absorption layer LA(320) is less than 20%, it may be difficult to finely pattern the absorption layer LA(320) and when the area of the absorption layer LA(320) exceeds 70%, the luminance of the sub-pixel emitting white (W) may decrease.

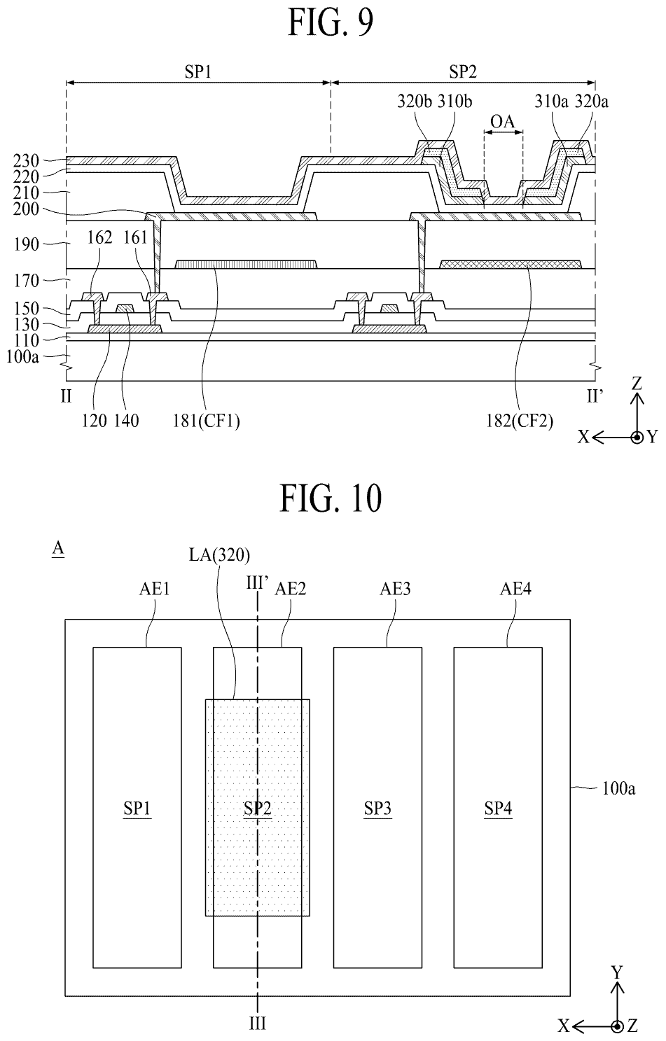

FIG. 9 is a cross-sectional view of a display device according to another embodiment of the present disclosure. In this case, FIG. 9 corresponds to the cross-section II-II′ of FIG. 8. Meanwhile, an embodiment of FIG. 9 is the same except for configurations of the metal buffer layer and the absorption layer, and thus different configurations will be mainly described below.

As shown in FIG. 9, a display device according to another embodiment of the present disclosure includes a first substrate 100a, a buffer layer 110, an active layer 120, a gate insulating layer 130, a gate electrode 140, an interlayer insulating layer 150, a source electrode 161, a drain electrode 162, a first planarization layer 170, a second planarization layer 190, a first color filter 181(CF1), a second color filter 182(CF2), a first electrode 200, a bank 210, a light emitting layer 220, a second electrode 230, a metal buffer layer 310, and an absorption layer 320.

According to another embodiment of the present disclosure, a portion of the upper surface of the first electrode 200 provided in the second sub-pixel SP2 and exposed by the bank 210 overlaps the absorption layer 320, and another portion of the upper surface of the first electrode 200 exposed by the bank 210 does not overlap the absorption layer 320.

The metal buffer layer 310 includes a first metal buffer layer 310a (also referred to as a first portion of the metal buffer layer 310) and a second metal buffer layer 310b (also referred to as a second portion of the metal buffer layer 310). In this case, the first metal buffer layer 310a is provided on one side of the second sub-pixel SP2, for example, on the right side, and the second metal buffer layer 310b is provided on another side, for example, on the left side, of the second sub-pixel SP2. In this case, the first metal buffer layer 310a and the second metal buffer layer 310b are spaced apart from each other, and a portion of the upper surface of the light emitting layer 220 may be exposed through a spaced region between the first metal buffer layer 310a and the second metal buffer layer 310b.

Likewise, the absorption layer 320 includes a first absorption layer 320a (also referred to as a first portion of the absorption layer 320) and a second absorption layer 320b (also referred to as a second portion of the absorption layer 320).

The first absorption layer 320a is provided on one side of the second sub-pixel SP2, for example, on the right side, and the second absorption layer 320b is provided on another side, for example, on the left side, of the second sub-pixel SP2. In this case, the first absorption layer 320a and the second absorption layer 320b are spaced apart from each other, and a portion of the upper surface of the light emitting layer 220 may be exposed through the spaced regions of the first absorption layer 320a and the second absorption layer 320b.

The second electrode 230 is formed on the light emitting layer 220 in the first sub-pixel SP1 and the second sub-pixel SP2. In this case, the second electrode 230 is formed on the absorption layer 320 in the second sub-pixel SP2. According to another embodiment of the present disclosure, the metal buffer layer 310 and the absorption layer 320 are formed to be spaced apart from each other from the center of the second sub-pixel SP2, such that in a region between the first metal buffer layer 310a and the second metal buffer layer 310b and a region between the first absorption layer 320a and the second absorption layer 320b, the second electrode 230 may be in contact with an upper surface of the light emitting layer 220.

According to another embodiment of the present disclosure, reflectance or light efficiency of the second sub-pixel SP2 emitting white W may be optimized by adjusting the distance between the first absorption layer 320a and the second absorption layer 320b and the distance between the first metal buffer layer 310a and the second metal buffer layer 310b.

Referring to FIG. 9, the second sub-pixel SP2 includes an opening area OA in the absorption layer 320. Here, the absorption layer 320 includes a first portion of the absorption layer 320 (i.e., first absorption layer 320a) and a second portion of the absorption layer 320 (i.e., second absorption layer 320b). The first portion of the absorption layer 320a and the second portion of the absorption layer 320b are spaced apart from each other at the opening area OA. Similarly, the metal buffer layer 310 includes a first portion of the metal buffer layer 310 (i.e., first metal buffer layer 310a) and a second portion of the metal buffer layer 310 (i.e., second metal buffer layer 310b).

As shown, the first portion of the metal buffer layer 310a overlaps with the first portion of the absorption layer 310a from a plan view and the second portion of the metal buffer layer 310b overlaps with the second portion of the absorption layer 320b from a plan view. The first portion of the metal buffer layer and the second portion of metal buffer layer are spaced apart from each other at the opening area OA. Similarly, the first portion of the absorption layer and the second portion of the absorption layer are spaced apart from each other at the opening area OA.

In the opening area OA, the second electrode 230 directly contacts the light emitting layer 220 at the opening area OA.

FIG. 10 is a plan view of a display device according to another embodiment of the present disclosure. In this case, FIG. 10 is an enlarged view of an area A of FIG. 2. Meanwhile, an embodiment of FIG. 10 shows another embodiment in which an area of the absorption layer is adjusted, and other configurations are the same as those of an embodiment of FIG. 8, and thus different configurations will be mainly described below.

As shown in FIG. 10, the display device according to another embodiment of the present disclosure may include a first sub-pixel SP1, a second sub-pixel SP2, a third sub-pixel SP3, and a fourth sub-pixel SP4. Specifically, the display device according to an embodiment of the present disclosure may include a first sub-pixel SP1, a second sub-pixel SP2, a third sub-pixel SP3, and a fourth sub-pixel SP4 provided on the first substrate 100a.

According to another embodiment of the present disclosure, an absorption layer LA(320) may be formed in the second sub-pixel SP2 emitting white W to correspond to the second sub-pixel SP2. The absorption layer LA(320) may be provided only in the second sub-pixel SP2, and may not be provided in the first sub-pixel SP1, the third sub-pixel SP3, and the fourth sub-pixel SP4.

According to another embodiment of the present disclosure, the absorption layer LA(320) may be formed to cover only a partial area without covering the entire surface of the second sub-pixel SP2. Meanwhile, in the case of FIG. 10, unlike the case in which the opening area OA is formed in a partial area of the absorption layer LA(320) in the embodiment of FIG. 8, the length of the absorption layer LA(320) may be formed to be shorter than the length of the portion AE2 of the second anode electrode in the vertical direction (Y direction). By forming in this way, it is possible to reduce the reflectance in the second sub-pixel SP2 and achieve high luminance.

The absorption layer LA(320) may expose a partial area without covering the entire surface of the second sub-pixel SP2. For example, the absorption layer LA(320) is formed to cover only a portion of the second sub-pixel SP2, for example, a center portion, and may expose another portion of the second sub-pixel SP2, for example, an upper portion or a lower portion of the second sub-pixel SP2.

A degree to which the second sub-pixel SP2 emitting white (W) is exposed to the outside may be controlled by adjusting an area of the absorption layer LA(320), and thus reflectance or light efficiency of the second sub-pixel SP2 emitting white (W) may be optimized. Specifically, by adjusting an area of the absorption layer LA(320) covering the second sub-pixel SP2 emitting white (W), light efficiency and reflectance in the second sub-pixel SP2 emitting white (W) may be controlled. Meanwhile, since the reflectance or light efficiency in the second sub-pixel SP2 according to the area of the absorption layer LA(320) is the same as described in Table 3, repeated contents will be omitted.

According to another configuration of the present disclosure, the area of the absorption layer LA(320) with respect to the portion AE2 of the second anode electrode may be 20% or more and 70% or less. When the area of the absorption layer LA(320) is less than 20%, it may be difficult to finely pattern the absorption layer LA(320), and when the area of the absorption layer LA(320) exceeds 70%, the luminance of the sub-pixel emitting white (W) may deteriorate.

In some embodiments, the absorption layer 320 at least partially overlaps the portion AE2 of the first electrode from a plan view (see FIGS. 8 and 10).

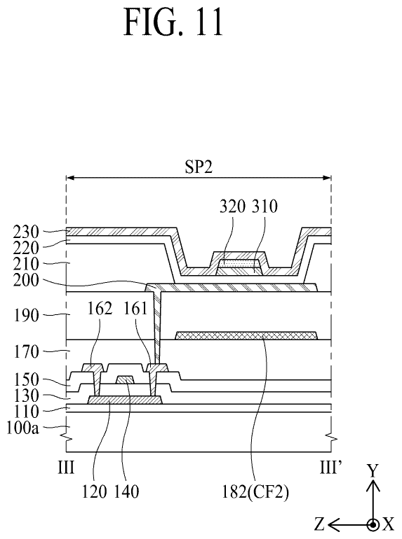

FIG. 11 is a cross-sectional view of a display device according to another embodiment of the present disclosure. In this case, FIG. 11 corresponds to the cross-section III-III′ of FIG. 10, which shows cross-sections of the first sub-pixel and the second sub-pixel. Meanwhile, an embodiment of FIG. 11 is the same as an embodiment of FIG. 9 except for the configurations of the metal buffer layer 310 and the absorption layer 320, and thus different configurations will be mainly described below.

As shown in FIG. 11, a display device according to another embodiment of the present disclosure includes a first substrate 100a, a buffer layer 110, an active layer 120, a gate insulating layer 130, a gate electrode 140, an interlayer insulating layer 150, a source electrode 161, a drain electrode 162, a first planarization layer 170, a second planarization layer 190, a first color filter 181(CF1), a second color filter 182(CF2), a first electrode 200, a bank 210, a light emitting layer 220, a second electrode 230, a metal buffer layer 310, and an absorption layer 320.

The metal buffer layer 310 and the absorption layer 320 are formed to cover centers of the first electrode 200 of the second sub-pixel SP2. Accordingly, a portion of the upper surface of the first electrode 200 on which the metal buffer layer 310 and the absorption layer 320 are not formed may be exposed to the outside. Furthermore, since the metal buffer layer 310 and the absorption layer 320 is not provided in one side, for example, the left side and another side, for example, the right side with respect to the centers of the first electrode 200 overlapping the metal buffer layer 310 and the absorption layer 320, the light emitting layer 220 may be in contact with the second electrode 230 in a partial region of the upper surface of the first electrode 200.

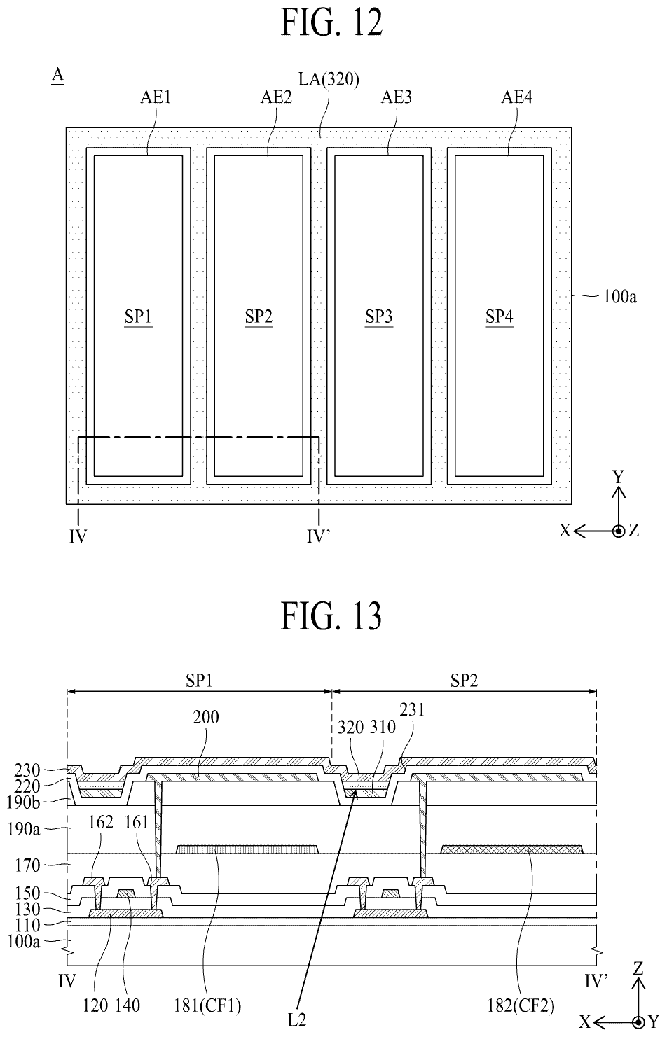

FIG. 12 is a plan view of a display device according to another embodiment of the present disclosure. In this case, FIG. 12 is an enlarged view of an area A of FIG. 2. Meanwhile, an embodiment of FIG. 12 is the same as an embodiment of FIG. 3 except for the configuration of the absorption layer, and thus different configurations will be mainly described below.

As shown in FIG. 12, the display device according to another embodiment of the present disclosure may include a first sub-pixel SP1, a second sub-pixel SP2, a third sub-pixel SP3, and a fourth sub-pixel SP4. Specifically, the display device according to another embodiment of the present disclosure may include a first sub-pixel SP1, a second sub-pixel SP2, a third sub-pixel SP3, and a fourth sub-pixel SP4 provided on the first substrate 100a. In some embodiments, the absorption layer 320 fully overlaps the portions AE1, AE2, AE3, AE4 of the first electrodes in the first to fourth sub-pixels SP1 to SP4 from a plan view.

According to another embodiment of the present disclosure, the absorption layer LA(320) may be formed in the boundary regions of the first sub-pixel SP1, the second sub-pixel SP2, the third sub-pixel SP3, and the fourth sub-pixel SP4. Accordingly, the absorption layer LA(320) may be provided to surround each of the sub-pixels SP1 to SP4. By forming as described above, external light introduced from the lower surface of the first substrate 100a is prevented from flowing into the boundary regions between each of the sub-pixels SP1 to SP4, thereby minimizing the reflection of external light and improving the user's visibility.

FIG. 13 is a cross-sectional view of a display device according to another embodiment of the present disclosure. In this case, FIG. 13 corresponds to the cross-section IV-IV′ of FIG. 12, and illustrates cross-sections of the first sub-pixel and the second sub-pixel.

As shown in FIG. 13, a display device according to another embodiment of the present disclosure includes a first substrate 100a, a buffer layer 110, an active layer 120, a gate insulating layer 130, a gate insulating layer 140, an interlayer insulating layer 150, a source electrode 161, a drain electrode 162, a first planarization layer 170, a first color filter 181(CF1), a second color filter 182(CF2), a third planarization layer 190a, a first electrode 200, a light emitting layer 220, a second electrode 230, a metal buffer layer 310, and an absorption layer 320. Meanwhile, a first substrate 100a, a buffer layer 110, an active layer 120, a gate insulating layer 130, a gate electrode 140, an interlayer insulating layer 150, a source electrode 161, a drain electrode 162, a first color filter 181(CF1), and a second planarization layer 190a provided in the display device according to an embodiment of FIG. 13 are the same as those provided in the display device according to the embodiment of FIG. 3, and repeated descriptions thereof will be omitted.

The third planarization layer 190b is formed on the second planarization layer 190a. The third planarization layer 190b may be patterned to correspond to the first sub-pixel SP1 and the second sub-pixel SP2, thereby exposing a portion of an upper surface of the second planarization layer 190a.

A contact hole may be provided in the third planarization layer 190b, and a portion of the upper surface of the source electrode 161 may be exposed by the contact hole. However, in some cases, a portion of the upper surface of the drain electrode 162 may be exposed by the contact hole. The third planarization layer 190b may be formed of an organic insulating layer material. For example, the third planarization layer 190b may be formed of an organic insulating material, such as an acrylic resin, an epoxy resin, a phenol resin, a polyamide resin, or a polyimide resin.

The first electrode 200 may be formed on the third planarization layer 190b, and may be electrically connected to the source electrode 161 through contact holes in the first planarization layer 170, the second planarization layer 190a, and the third planarization layer 190b. The first electrode 200 may function as an anode electrode. The first electrode 200 may correspond to the first sub-pixel SP1 and the second sub-pixel SP2, and the first electrode 200 provided in the first sub-pixel SP1 may correspond to the first anode electrode (see AE1 of FIG. 12), and the second electrode 200 provided in the second sub-pixel SP2 may correspond to the second anode electrode (see AE2 of FIG. 12).

The first electrode 200 may be formed of, for example, a transparent electrode. Therefore, light emitted from the light emitting layer 220 of the first sub-pixel SP1 and the second sub-pixel SP2 may pass through the first electrode 200 and be emitted toward the first substrate 100a. However, the present disclosure is not limited thereto.

Meanwhile, according to another embodiment of the present disclosure, unlike the embodiments of FIGS. 4, 9 and 11, a bank may not be formed on the first electrode 200. The first electrode 200 is formed on an upper surface of the third planarization layer 190b, and the upper surface of the first electrode 200 may be defined as a light emitting area.

The light emitting layer 220 may be formed on the first electrode 200. The light emitting layer 220 may be formed of, for example, a white light emitting layer connected to all pixels. When the light emitting layer 220 is formed of a white light emitting layer, the light emitting layer 220 may include, for example, a first stack including a blue light emitting layer, a second stack including a yellow-green light emitting layer, and a charge generation layer provided between the first stack and the second stack, and the light emitting layer 220 may include, for example, a first stack including a blue light emitting layer, a second stack including a yellow-green light emitting layer, for example, a third stack including a blue light emitting layer, a first charge generation layer provided between the first stack and the second stack, and a second charge generation layer provided between the second stack and the third stack, but is not limited thereto.

According to another embodiment of the present disclosure, the light emitting layer 220 may be in contact with a portion of the upper surface of the second planarization layer 190a and a portion of the upper surface and a side surface of the third planarization layer 190b. Meanwhile, the present disclosure is not limited thereto, and the light emitting layer 220 may be formed in a pattern so that the light emitting layer 220 is not continuous with each other between the first sub-pixel SP1 and the second sub-pixel SP2.

The second electrode 230 may be formed on the light emitting layer 220. The second electrode 230 may function as a cathode.

The second electrode 230 may be formed, for example, on the entire surface of the light emitting layer 220. Accordingly, the second electrode 230 may be formed on the entire surfaces of the first sub-pixel SP1 and the second sub-pixel SP2.

The second electrode 230 may be formed as, for example, a reflective electrode. Therefore, light emitted from the light emitting layer 220 of the first sub-pixel SP1 and the second sub-pixel SP2 may be reflected by the second electrode 230 and may pass through the first electrode 200 to be emitted toward the first substrate 100a. However, the present disclosure is not limited thereto.

According to another embodiment of the present disclosure, the second electrode 230 may be formed to be concave from the first substrate 100a by a boundary region between the first sub-pixel SP1 and the second sub-pixel SP2, specifically, a step formed in a region where a portion of the upper surface of the second planarization layer 190a is exposed. In this case, as the second electrode 230 is formed to be concave, an inclined surface 231 provided to surround the first electrode 200 and the light emitting layer 220 may be formed on the second electrode 230.

Light emitted from the light emitting layer 220 of the first sub-pixel SP1 and/or the second sub-pixel SP2 is reflected by the inclined surface 231 of the second electrode 230 to further increase the efficiency of light emitted to the first substrate 100a.

According to another embodiment of the present disclosure, a metal buffer layer 310 formed on the light emitting layer 220 and an absorption layer 320 formed on the metal buffer layer 310 and provided under the second electrode 230 may be additionally provided in a boundary region between the first sub-pixel SP1 and the second sub-pixel SP2, specifically in a region where a portion of the upper surface of the second planarization layer 190a is exposed.

The metal buffer layer 310 may be formed on the light emitting layer 220. However, the present disclosure is not limited thereto, and when the light emitting layer 220 is patterned to correspond to the first sub-pixel SP1 and the second sub-pixel SP2, the metal buffer layer 310 may be in contact with an upper surface of the second planarization layer 190a exposed from the third planarization layer 190b.

The metal buffer layer 310 may include the same material as the second electrode 230. The metal buffer layer 310 may include, for example, aluminum (Al), but is not limited thereto, and may include various materials according to the level of the art.

The metal buffer layer 310 may allow electrons to be smoothly injected from the second electrode 230 into the light emitting layer 220 according to the energy level of the light emitting layer 220 and the absorption layer 320.

The absorption layer 320 may be formed on the metal buffer layer 310 in the second sub-pixel SP2. The absorption layer 320 may include an oxygen-deficient metal oxide. The absorption layer 320 may include, for example, an oxygen-deficient aluminum oxide (Al2Ox, in this case, x is greater than 0 and less than 3) or an oxygen-deficient zinc oxide (ZnOy, in this case, y is greater than 0 and less than 1), but is not limited thereto.

According to another embodiment of the present disclosure, since the metal buffer layer 310 and the absorption layer 320 are provided in the boundary region between the first sub-pixel SP1 and the second sub-pixel SP2, even if the external light L2 flowing from the outside of the first substrate 100a flows into the boundary region between the first sub-pixel SP1 and the second sub-pixel SP2, the absorption layer 320 absorbs or blocks the external light L2, thereby preventing or minimizing the reflection of the external light L2 to the second electrode 230.

Accordingly, according to an embodiment of the present disclosure, it is possible to lower the reflectance of external light at the boundary between a plurality of sub-pixels (see SP1 to SP4 of FIG. 12), thereby improving the user's visual sense.

Accordingly, the present disclosure may have the following advantages.

According to an embodiment of the present disclosure, by providing an absorption layer under the second electrode of the sub-pixel emitting white light, it is possible to reduce the reflectance of the sub-pixel emitting white light by preventing external light introduced from the lower portion of the substrate from being reflected by the second electrode. Accordingly, it is possible to reduce or minimize the decrease in the user's visual sense due to the reflection of external light.

According to an embodiment of the present disclosure, it is not necessary to attach a separate film, for example, a polarizing film, for preventing reflection of external light by lowering the reflectance of the sub-pixels emitting white light. Since a separate film for preventing reflection of external light is not attached, the sub-pixels having high luminance and excellent contrast ratio can be implemented.

According to an embodiment of the present disclosure, by providing a color filter for passing light of a specific wavelength band in a sub-pixel emitting white light, the color temperature of the light emitted from the light emitting layer can be increased, thereby implementing white with improved luminance and light efficiency.

According to an embodiment of the present disclosure, since the absorption layer is formed in the boundary region between the sub-pixels, external light introduced from the lower portion of the substrate may be prevented from being reflected to the second electrode in the boundary region between the sub-pixels. Accordingly, it is possible to reduce or minimize the decrease in the user's visual sense.

It will be apparent to those skilled in the art that various substitutions, modifications, and variations are possible within the scope of the present disclosure without departing from the spirit and scope of the present disclosure. Therefore, the scope of the present disclosure is represented by the following claims, and all changes or modifications derived from the meaning, range and equivalent concept of the claims should be interpreted as being included in the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a substrate including a first sub-pixel and a second sub-pixel;
a first electrode on the substrate and on each of the first sub-pixel and the second sub-pixel;
a light emitting layer on the first electrode;
an absorption layer on the light emitting layer and disposed in the first sub-pixel; and
a second electrode on the light emitting layer,
wherein the absorption layer disposed in the first sub-pixel is disposed under the second electrode.

2. The display device according to claim 1, further comprising:
a metal buffer layer disposed between the light emitting layer and the absorption layer in the first sub-pixel;
wherein the metal buffer layer includes a same material as the second electrode.

3. The display device according to claim 1,
wherein a distance between the first electrode and the second electrode in the first sub-pixel is greater than a distance between the first electrode and the second electrode in the second sub-pixel.

4. The display device according to claim 1,
wherein the first electrode is a transparent electrode and the second electrode is a reflective electrode.

5. The display device according to claim 1, further comprising:
a bank on the first electrode of the first sub-pixel to partition the first sub-pixel,
wherein the absorption layer overlaps an entire upper surface of the first electrode exposed by the bank.

6. The display device according to claim 1, further comprising:
a bank on the first electrode of the first sub-pixel to partition the first sub-pixel,
wherein the absorption layer overlaps a portion of an upper surface of the first electrode exposed by the bank, and
wherein another portion of the upper surface of the first electrode that does not overlap the absorption layer is exposed to an outside.

7. The display device according to claim 6,
wherein the absorption layer includes a first absorption layer and a second absorption layer spaced apart from the first absorption layer,
wherein the first absorption layer and the second absorption layer are on a same layer, and
wherein another portion of the upper surface of the first electrode is exposed through a spaced area between the first absorption layer and the second absorption layer.

8. The display device according to claim 7,
wherein the second electrode is in contact with the light emitting layer in the spaced area between the first absorption layer and the second absorption layer.

9. The display device according to claim 6,
wherein the portion of the upper surface of the first electrode overlapping the absorption layer of the first electrode is 20% or more and 70% or less of the area of the first electrode exposed by the bank.

10. The display device according to claim 1, further comprising:
a color filter on the substrate and disposed under the first electrode,
wherein the color filter includes a first color filter corresponding to the first sub-pixel and a second color filter corresponding to the second sub-pixel, and
wherein the first color filter and the second color filter transmit light of different wavelength bands.

11. The display device according to claim 10,
wherein the first color filter is disposed so that a transmittance for light in a wavelength range greater than or equal to 380 nm and less than 530 nm and greater than or equal to 570 nm and less than 780 nm to a transmittance for light in a wavelength range greater than or equal to 530 nm and less than 570 nm is greater than or equal to 85% and less than or equal to 95%.

12. The display device according to claim 10,
wherein the first sub-pixel emits white light by the first color filter, and
wherein the second sub-pixel emits light of any one of red, green, and blue colors by the second color filter.

13. A display device, comprising:
a substrate including a first sub-pixel emitting white light and a second sub-pixel emitting different color from the first sub-pixel;
an absorption layer overlapping at least a portion of the first sub-pixel; and
a reflective layer disposed to cover the absorption layer,
wherein the reflective layer overlaps the first sub-pixel and the second sub-pixel.

14. The display device according to claim 13,
wherein the absorption layer covers an entire first sub-pixel.

15. The display device according to claim 13,
wherein an open area is disposed in a partial area of the absorption layer to expose an upper surface of an anode electrode disposed in the first sub-pixel.

16. The display device according to claim 13, further comprising:
a first color filter corresponding to the first sub-pixel,
wherein the first color filter is disposed so that a transmittance for light in a wavelength range greater than or equal to 380 nm and less than 530 nm and greater than or equal to 570 nm and less than 780 nm to a transmittance for light in a wavelength range greater than or equal to 530 nm and less than 570 nm is greater than or equal to 85% and less than or equal to 95%.

17. A display device, comprising:
a substrate including a first sub-pixel and a second sub-pixel;
a first electrode on the substrate and on each of the first sub-pixel and the second sub-pixel;
a light emitting layer on the first electrode;
a second electrode on the light emitting layer and concavely disposed in an area between the first sub-pixel and the second sub-pixel; and
an absorption layer between the first sub-pixel and the second sub-pixel,
wherein the absorption layer is disposed below the second electrode in a region between the first sub-pixel and the second sub-pixel.

18. The display device according to claim 17, further comprising:
a buffer layer disposed between the light emitting layer and the absorption layer,
wherein the buffer layer includes a same material as the second electrode.

19. The display device according to claim 17, further comprising:
a color filter on the substrate and disposed under the first electrode,
wherein the color filter includes a first color filter corresponding to the first sub-pixel and a second color filter corresponding to the second sub-pixel, and
wherein the first color filter and the second color filter transmit light of different wavelength bands.

20. The display device according to claim 19,
wherein the first color filter is disposed so that a transmittance for light in a wavelength range greater than or equal to 380 nm and less than 530 nm and greater than or equal to 570 nm and less than 780 nm to a transmittance for light in a wavelength range greater than or equal to 530 nm and less than 570 nm is greater than or equal to 85% and less than or equal to 95%.
